(19) United States
(12) Patent Application Publication
(10) Pub. No.: US 2025/0113546 A1
(43) Pub. Date: Apr. 3, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Kentaro MIURA, Tokyo (JP); Takeshi SAKAI, Tokyo (JP); Akihiro HANADA, Tokyo (JP); Masahiro WATABE, Tokyo (JP)

(73) Assignee: Japan Display Inc., Tokyo (JP)

(21) Appl. No.: 18/897,024

(22) Filed: Sep. 26, 2024

(30) Foreign Application Priority Data
Sep. 29, 2023 (JP) 2023-170309

(51) Int. Cl. H01L 29/786; H01L 29/417; H01L 29/423

(52) U.S. Cl. CPC H10D 30/6756; H10D 30/6729; H10D 30/673; H10D 30/6757

(57) ABSTRACT

A semiconductor device includes a gate electrode, an oxide semiconductor layer having a polycrystalline structure, and a gate insulating layer between the gate electrode and the oxide semiconductor layer. The oxide semiconductor layer includes a source region and a drain region each containing an impurity element, a channel region between the source region and the drain region, and a first region adjacent to the channel region. The first region includes a first edge extending along a first direction travelling from the source region to the drain region. The first region has a higher electrical resistivity than each of the source region and the drain region. An etching rate of the oxide semiconductor layer is less than 3 nm/min when the oxide semiconductor layer is etched using an etching solution containing phosphoric acid as a main component at 40° C.

### CROSS-REFERENCE TO RELATED APPLICATION

This application claims the benefit of priority to Japanese Patent Application No. 2023-170309, filed on Sep. 29, 2023, the entire contents of which are incorporated herein by reference.

### FIELD

An embodiment of the present invention relates to a semiconductor device using an oxide semiconductor having a polycrystalline structure.

### BACKGROUND

In recent years, instead of a silicon semiconductor film using amorphous silicon, low-temperature polysilicon, and single-crystal silicon, a semiconductor device including an oxide semiconductor film has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film has a simple structure and can be manufactured by a low-temperature process, similar to a semiconductor device including an amorphous silicon film. Further, the semiconductor device including an oxide semiconductor film is known to have a higher field effect mobility than the semiconductor device including an amorphous silicon film.

### SUMMARY

A semiconductor device according to an embodiment of the present invention includes a gate electrode, an oxide semiconductor layer having a polycrystalline structure, a gate insulating layer between the gate electrode and the oxide semiconductor layer, a source electrode over the oxide semiconductor layer, and a drain electrode over the oxide semiconductor layer. The oxide semiconductor layer includes a source region containing an impurity element electrically connected to the source electrode, a drain region containing the impurity element electrically connected to the drain electrode, a channel region between the source region and the drain region, and a first region adjacent to the channel region. The first region includes a first edge extending along a first direction travelling from the source region to the drain region. The first region has a higher electrical resistivity than each of the source region and the drain region. An etching rate of the oxide semiconductor layer is less than 3 nm/min when the oxide semiconductor layer is etched using an etching solution containing phosphoric acid as a main component at 40° C.

A semiconductor device according to an embodiment of the present invention includes a gate electrode extending in a first direction, an oxide semiconductor layer having a polycrystalline structure, a gate insulating layer between the gate electrode and the oxide semiconductor layer, a source electrode over the oxide semiconductor layer, and a drain electrode over the oxide semiconductor layer. The oxide semiconductor layer includes a first edge and a second edge each extending in a second direction orthogonal to the first direction. In a plan view, the oxide semiconductor layer includes a first region overlapping the gate electrode, a source region containing an impurity element adjacent to the first region, a drain region containing the impurity element adjacent to the first region, a second region surrounded by the source region, a third region surrounded by the source region, a fourth region surrounded by the drain region, and a fifth region surrounded by the drain region. The source region is electrically connected to the source electrode through a first contact hole. The drain region is electrically connected to the drain electrode through a second contact hole. The second region includes a part of the first edge. The third region includes a part of the second edge. The fourth region includes a part of the first edge. The fifth region includes a part of the second edge. Each of the first region, the second region, the third region, the fourth region, and the fifth region has a higher electrical resistivity than each of the source region and the drain region. An etching rate of the oxide semiconductor layer is less than 3 nm/min when the oxide semiconductor layer is etched using an etching solution containing phosphoric acid as a main component at 40° C.

A semiconductor device includes a gate electrode extending in a first direction, an oxide semiconductor layer having a polycrystalline structure, a gate insulating layer between the gate electrode and the oxide semiconductor layer, a source electrode over the oxide semiconductor layer, and a drain electrode over the oxide semiconductor layer. The oxide semiconductor layer includes a first edge and a second edge each extending in a second direction orthogonal to the first direction. In a plan view, the oxide semiconductor layer includes a first region overlapping the gate electrode, a source region containing an impurity element adjacent to the first region, and a drain region containing the impurity element adjacent to the first region. The source region is electrically connected to the source electrode through a first contact hole. The drain region is electrically connected to the drain electrode through a second contact hole. The first region has a higher electrical resistivity than each of the source region and the drain region. In the plan view, a first distance from the first edge to the first contact hole in the first direction is greater than a second distance from the first region to the first contact hole in the second direction. An etching rate of the oxide semiconductor layer is less than 3 nm/min when the oxide semiconductor layer is etched at 40° C. using an etching solution containing phosphoric acid as a main component.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of an oxide semiconductor layer of a semiconductor device according to an embodiment of the present invention.

FIG. 3A is a schematic cross-sectional view illustrating a method for forming a source region and a drain region in an oxide semiconductor layer of a semiconductor device according to an embodiment of the present invention.

FIG. 3B is a schematic cross-sectional view illustrating a method for forming a source region and a drain region in an oxide semiconductor layer of a semiconductor device according to an embodiment of the present invention.

FIG. 4 is a schematic plan view showing a configuration of an oxide semiconductor layer of a semiconductor device according to a modification of an embodiment of the present invention.

FIG. 5 is a schematic cross-sectional view showing a method for forming a source region and a drain region in an oxide semiconductor layer of a semiconductor device according to a modification of an embodiment of the present invention.

FIG. 6 is a schematic plan view showing a configuration of an oxide semiconductor layer of a semiconductor device according to a modification of the embodiment of the present invention.

FIG. 7 is a schematic plan view showing a configuration of an oxide semiconductor layer of a semiconductor device according to a modification of an embodiment of the present invention.

FIG. 8 is a schematic plan view showing a configuration of an oxide semiconductor layer of a semiconductor device according to a modification of the embodiment of the present invention.

FIG. 9 is a cross-sectional view showing a configuration of a semiconductor device according to a modification of an embodiment of the present invention.

FIG. 10 is a schematic plan view showing a configuration of an oxide semiconductor layer of a semiconductor device according to an embodiment of the present invention.

FIG. 11 is a schematic plan view showing a configuration of an oxide semiconductor layer of a semiconductor device according to an embodiment of the present invention.

FIG. 12 is a schematic plan view showing a configuration of an oxide semiconductor layer of a semiconductor device according to a modification of an embodiment of the present invention.

FIG. 13 is a schematic plan view showing a configuration of an oxide semiconductor layer of a semiconductor device according to an embodiment of the present invention.

FIG. 14A is a schematic cross-sectional view showing a configuration of a semiconductor device according to an embodiment of the present invention.

FIG. 14B is a schematic cross-sectional view showing a configuration of a semiconductor device according to an embodiment of the present invention.

FIG. 15A is a schematic cross-sectional view showing a method for manufacturing an oxide semiconductor layer of a semiconductor device according to an embodiment of the present invention.

FIG. 15B is a schematic cross-sectional view showing a method for manufacturing an oxide semiconductor layer of a semiconductor device according to an embodiment of the present invention.

FIG. 15C is a schematic cross-sectional view illustrating a method for manufacturing an oxide semiconductor layer of a semiconductor device according to an embodiment of the present invention.

FIG. 16 is a schematic cross-sectional view of a semiconductor device according to an embodiment of the present invention.

### DESCRIPTION OF EMBODIMENTS

A semiconductor device is required to have not only a high field effect mobility but also high reliability. An embodiment of the present invention can provide a semiconductor device having high reliability.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a semiconductor device” means a positional relationship in which the semiconductor device and the pixel electrode overlap in a plan view. In addition, a plan view refers to viewing from a direction perpendicular to a surface of the substrate.

In the present specification and the like, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction.

In the specification and the like, the terms “film” and “layer” can be optionally interchanged with one another.

In addition, the following embodiments can be combined with each other as long as there is no technical contradiction.

### First Embodiment

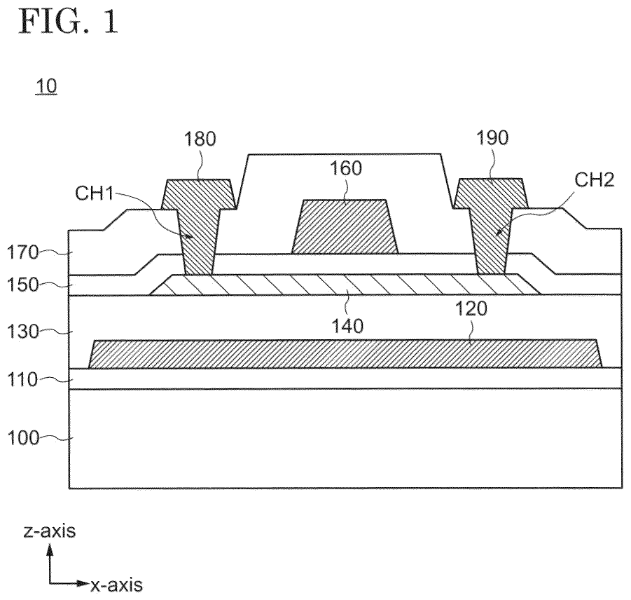

A semiconductor device 10 according to an embodiment of the present invention is described with reference to FIGS. 1 to 3B.

### [1. Configuration of Semiconductor Device 10]

FIG. 1 is a schematic cross-sectional view showing a configuration of the semiconductor device 10 according to an embodiment of the present invention.

As shown in FIG. 1, the semiconductor device 10 includes a substrate 100, a first insulating layer 110, a light shielding layer 120, a second insulating layer 130, an oxide semiconductor layer 140, a gate insulating layer 150, a gate electrode 160, a third insulating layer 170, a source electrode 180, and a drain electrode 190. The first insulating layer 110 is provided on the substrate 100. The light shielding layer 120 is provided on the first insulating layer 110. The second insulating layer 130 is provided on the first insulating layer 110 so as to cover an upper surface and an edge surface of the light shielding layer 120. The oxide semiconductor layer 140 is provided on the second insulating layer 130. The gate insulating layer 150 is provided on the second insulating layer 130 so as to cover an upper surface and an edge surface of the oxide semiconductor layer 140. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The source electrode 180 and the drain electrode 190 are provided on the third insulating layer 170. The source electrode 180 is in contact with the oxide semiconductor layer 140 through a contact hole CH1 that penetrates the gate insulating layer 150 and the third insulating layer 170. The drain electrode 190 is in contact with the oxide semiconductor layer 140 through a contact hole CH2 that penetrates the gate insulating layer 150 and the third insulating layer 170. The source electrode 180 and the drain electrode 190 are electrically connected to the oxide semiconductor layer 140.

The substrate 100 can support each layer constituting the semiconductor device 10. For example, a rigid substrate having light-transmitting properties, such as a glass substrate, a quartz substrate, or a sapphire substrate, can be used as the substrate 100. Further, a rigid substrate having no light-transmitting properties, such as a silicon substrate, can also be used as the substrate 100. A flexible substrate having light-transmitting properties, such as a polyimide resin substrate, an acrylic resin substrate, a siloxane resin substrate, or a fluorine resin substrate, can also be used as the substrate 100. Impurities may be introduced into the flexible substrate in order to improve the heat resistance of the substrate 100.

The first insulating layer 110 can suppress diffusion of impurities from the substrate 100 or the outside. For example, an oxide such as silicon oxide (SiOₓ), silicon oxynitride (SiOₓN_{y}), aluminum oxide (AlOₓ), or aluminum oxynitride (AlOₓN_{y}), or a nitride such as silicon nitride (SiNₓ), silicon nitride oxide (SiNₓO_{y}), aluminum nitride (AlNₓ), or aluminum nitride oxide (AlNₓO_{y}) can be used for the first insulating layer 110. The first insulating layer 110 may have a single layer structure or a stacked structure.

Here, silicon oxynitride (SiOₓN_{y}) and aluminum oxynitride (AlOₓN_{y}) are oxides that contain a smaller proportion (x>y) of nitrogen (N) than oxygen (O). Further, silicon nitride oxide (SiNₓO_{y}) and aluminum nitride oxide (AlNₓO_{y}) are nitrides that contain a smaller proportion (x>y) of oxygen than nitrogen. In addition, silicon oxide (SiOₓ) and silicon oxynitride (SiOₓN_{y}) may be simply referred to as “silicon oxide” and silicon nitride (SiNₓ) and silicon nitride oxide (SiNₓO_{y}) may be simply referred to as “silicon nitride,” for convenience of explanation. Similarly, aluminum oxide (AlOₓ) and aluminum oxynitride (AlOₓN_{y}) may be simply referred to as “aluminum oxide” and aluminum nitride (AlNₓ) and aluminum nitride oxide (AlNₓO_{y}) may be simply referred to as “aluminum nitride.”

The light shielding layer 120 can reflect or absorb light incident on the side of the substrate 100. In other words, the light shielding layer 120 can shield light incident on the oxide semiconductor layer 140. For example, a metal such as aluminum (Al), copper (Cu), titanium (Ti), molybdenum (Mo), or tungsten (W), or an alloy or compound thereof can be used for the light shielding layer 120. Further, when the light shielding layer 120 does not require to be conductive, the light shielding layer 120 may not contain a metal. When the light shielding layer 120 does not contain a metal, a black matrix made of a black resin can be used for the light shielding layer 120. The light shielding layer 120 may have a single layer structure or a stacked structure. For example, the light shielding layer 120 may have a stacked structure including a red color filter, a green color filter, and a blue color filter.

The second insulating layer 130 can suppress the diffusion of impurities from the light shielding layer 120. Further, when the light shielding layer 120 has conductivity, the second insulating layer 130 can electrically insulate the light shielding layer 120 from the oxide semiconductor layer 140. For example, an oxide or a nitride similar to that of the first insulating layer 110 can be used for the second insulating layer 130. The second insulating layer 130 may have a single layer structure or a stacked structure. For example, the second insulating layer 130 may have a stacked structure including a silicon oxide film and a silicon nitride film.

Although the detailed configuration of the oxide semiconductor layer 140 is described later, when the oxide semiconductor layer 140 comes into contact with a nitride, oxygen deficiencies may be generated in the oxide semiconductor layer 140, or hydrogen may be supplied to the oxide semiconductor layer 140. In this case, the conductivity of the oxide semiconductor layer 140 increases, so that the semiconductor properties of the oxide semiconductor layer 140 are lost. Therefore, it is preferable to use an oxide for the second insulating layer 130 in contact with the oxide semiconductor layer 140. Specifically, when the second insulating layer 130 has a stacked structure including a silicon oxide film and a silicon nitride film, the silicon oxide film is provided on the silicon nitride film so that the silicon oxide film is in contact with the oxide semiconductor layer 140.

The gate insulating layer 150 is located between the oxide semiconductor layer 140 and the gate electrode 160, and can electrically insulate the oxide semiconductor layer 140 from the gate electrode 160. An oxide or a nitride similar to that of the first insulating layer 110 can be used for the gate insulating layer 150. The gate insulating layer 150 may have a single layer structure or a stacked layer structure.

As described above, when the oxide semiconductor layer 140 is in contact with a nitride, hydrogen may be supplied to the oxide semiconductor layer 140. Therefore, it is preferable to use an oxide for the gate insulating layer 150 in contact with the oxide semiconductor layer 140. Specifically, silicon oxide is used for the gate insulating layer 150.

The gate electrode 160 functions as an electrode that forms a channel in the oxide semiconductor layer 140. For example, a metal such as copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or compound thereof can be used for the gate electrode 160. The gate electrode 160 may have a single layer structure or a stacked layer structure.

The third insulating layer 170 can suppress diffusion of impurities from the outside. For example, an oxide or a nitride similar to that of the first insulating layer 110 can be used for the third insulating layer 170. The third insulating layer 170 may have a single layer structure or a stacked layer structure.

Each of the source electrode 180 and the drain electrode functions as an input electrode or an output electrode of a current flowing through the oxide semiconductor layer 140. For example, a metal, an alloy, or a compound similar to that of the gate electrode can be used for the source electrode 180 and the drain electrode 190. The source electrode 180 and the drain electrode may have a single layer structure or a stacked layer structure.

The semiconductor device 10 described above is a so-called top-gate transistor. The semiconductor device 10 can be modified in various ways. For example, when the light shielding layer 120 is conductive, the semiconductor device 10 may be configured such that the light shielding layer 120 functions as a gate electrode and the second insulating layer 130 functions as a gate insulating layer. In this case, the semiconductor device 10 is a so-called dual-gate transistor. Further, when the light shielding layer 120 is conductive, the light shielding layer 120 may be a floating electrode or may be connected to the source electrode 180. Furthermore, the semiconductor device 10 may be a so-called bottom-gate transistor in which the light shielding layer 120 functions as a main gate electrode.

### [2. Configuration of Oxide Semiconductor Layer 140]

### [2-1. Composition of Oxide Semiconductor Layer 140]

An oxide semiconductor containing two or more metal elements including indium (In) is used for the oxide semiconductor layer 140. Gallium (Ga), zinc (Zn), aluminum (Al), hafnium (Hf), yttrium (Y), zirconium (Zr), and lanthanoids are used as a metal element other than indium.

The oxide semiconductor layer 140 has light-transmitting properties and a polycrystalline structure including a plurality of crystal grains. It is preferable to use an oxide semiconductor in which the ratio of indium to all metal elements is greater than or equal to 50% in an atomic ratio so that the oxide semiconductor layer 140 has a polycrystalline structure. When the ratio of the indium is increased, the oxide semiconductor layer 140 is easily crystallized. Further, it is preferable that gallium is included in the metal elements other than indium. Gallium belongs to the same Group 13 elements as indium. Therefore, the crystallinity of the oxide semiconductor layer 140 is hardly inhibited by gallium.

Although the details are described later, the oxide semiconductor layer 140 has properties different from a conventional oxide semiconductor having a polycrystalline structure. Therefore, in order to distinguish the oxide semiconductor included in the oxide semiconductor layer 140 from the conventional oxide semiconductor having a polycrystalline structure, the oxide semiconductor contained in the oxide semiconductor layer 140 is referred to as Poly-crystalline Oxide Semiconductor (Poly-OS) in the following description.

The Poly-OS contained in the oxide semiconductor layer 140 can be formed by a sputtering method and a heat treatment. Here, a method for forming the oxide semiconductor layer 140 is described.

First, an oxide semiconductor film is deposited using a sputtering method. The oxide semiconductor film to be deposited has an amorphous structure. Here, the amorphous structure refers to a structure in which a long-range ordered structure does not exist and a periodic crystal lattice arrangement is not observed. For example, when the oxide semiconductor film having an amorphous structure is observed by X-ray diffraction (XRD), specific peaks due to a crystal structure are not obtained in the diffraction pattern. In addition, the oxide semiconductor film having an amorphous structure may have a short-range ordered structure in a microscopic region. However, such an oxide semiconductor film does not exhibit characteristics of Poly-OS and can be classified as the oxide semiconductor film having an amorphous structure.

The oxide semiconductor film having an amorphous structure is deposited at a low temperature. For example, the temperature of the substrate on which the oxide semiconductor film is deposited is lower than or equal to 150° C., preferably lower than or equal to 100° C., and more preferably lower than or equal to 50° C. When the temperature of the substrate is high, it is likely to generate microcrystals in the oxide semiconductor film to be deposited. Further, the oxygen partial pressure in the chamber during film formation is greater than or equal to 1% and less than or equal to 10%, preferably greater than or equal to 1% and less than or equal to 5%, and more preferably greater than or equal to 2% and less than or equal to 4%. When the oxygen partial pressure is large, microcrystals are generated in the oxide semiconductor film due to excess oxygen contained in the oxide semiconductor. On the other hand, under the condition where the oxygen partial pressure is less than 1%, the oxygen composition in the oxide semiconductor film becomes non-uniform, and an oxide semiconductor film including many microcrystals or an oxide semiconductor film that does not crystallize even when a heat treatment is performed is deposited.

Next, a heat treatment is performed on the oxide semiconductor film formed using a sputtering method. Although the heat treatment is performed in air, the atmosphere is not limited thereto. The temperature of the heat treatment is higher than or equal to 300° C. and lower than or equal to 500° C., and preferably higher than or equal to 350° C. and lower than or equal to 450° C. The time of the heat treatment is greater than or equal to 15 minutes and less than or equal to 120 minutes, and preferably greater than or equal to 30 minutes and less than or equal to 60 minutes. When the heat treatment is performed, the oxide semiconductor film having an amorphous structure is crystallized, and the oxide semiconductor layer 140 containing Poly-OS is formed.

The composition of the oxide semiconductor layer 140 is approximately the same as that of the sputtering target. Therefore, the composition of the metal elements of the oxide semiconductor layer 140 can be specified based on the composition of the metal elements of the sputtering target. The composition of the oxide semiconductor layer 140 may be specified using the XRD method. Specifically, the composition of the metal elements of the oxide semiconductor layer 140 can be specified based on the crystal structure and lattice constant of the oxide semiconductor layer 140 obtained by the XRD method. Further, the composition of the metal elements of the oxide semiconductor layer 140 can also be specified using X-ray fluorescence analysis or Electron Probe Micro Analyzer (EPMA) analysis. In addition, oxygen contained in the oxide semiconductor layer 140 is not limited thereto because oxygen changes depending on the process conditions for a sputtering method and the like.

### [2-2. Characteristics of Oxide Semiconductor Layer 140]

Next, characteristics of the oxide semiconductor layer 140 containing Poly-OS are described.

The oxide semiconductor layer 140 has excellent etching resistance. Specifically, the etching rate of the oxide semiconductor layer 140 is very small when the oxide semiconductor layer 140 is etched using an etching solution for wet etching. This means that the oxide semiconductor layer 140 is hardly etched by the etching solution. The etching rate when the oxide semiconductor layer 140 is etched using an etching solution containing phosphoric acid as a main component at 40° C. (hereinafter, referred to as a “mixed acid etching solution”) is less than 3 nm/min, less than 2 nm/min, or less than 1 nm/min. The ratio of phosphoric acid in the mixed acid etching solution is greater than or equal to 50%, greater than or equal to 60%, or greater than or equal to 70%. The mixed acid etching solution may contain acetic acid and nitric acid in addition to phosphoric acid. In addition, when an oxide semiconductor film not containing Poly-OS, for example, the oxide semiconductor film having an amorphous structure before the heat treatment, is etched using the mixed acid etching solution at 40° C., the etching rate of the oxide semiconductor film is greater than or equal to 100 nm/min. The etching rate when the oxide semiconductor layer 140 is etched using 0.5% of a hydrofluoric acid solution at room temperature is less than 5 nm/min, less than 4 nm/min, or less than 3 nm/min. When the oxide semiconductor film not containing Poly-OS is etched using 0.5% of the hydrofluoric acid solution at room temperature, the etching rate of the oxide semiconductor film is greater than or equal to 15 nm/min. Here, “40° C.” refers to 40±5° C. and may be the temperature of the etching solution or the set temperature of the etching solution. Further, “room temperature” refers to 25±5° C.

Examples of the oxide semiconductor layer 140 are shown in Table 1. Table 1 shows the etching rates of each of the prepared samples with respect to a mixed acid etching solution (“Mixed Acid AT-2F” manufactured by Rasa Kogyo Co., Ltd., in which the ratio of phosphoric acid in the mixed acid etching solution is 65%) and 0.5% of a hydrofluoric acid solution. When each sample was etched, the temperature of the mixed acid etching solution was 40° C., and the temperature of 0.5% of the hydrofluoric acid solution was room temperature. In Table 1, Sample 1 is the oxide semiconductor layer 140 containing Poly-OS, Sample 2 is an oxide semiconductor film having an amorphous structure before the heat treatment, and Sample 3 is an oxide semiconductor film containing indium gallium zinc oxide (IGZO) in which the ratio of indium is less than 50%.

TABLE 1

| | Mixed acid | 0.5% of hydrofluoric |
|---|---|---|
| | etching solution | acid solution |
| Sample 1 | <0.1 nm/min | <2 nm/min |
| Sample 2 | 111 nm/min | >18 nm/min |
| Sample 3 | 162 nm/min | — |

As shown in Table 1, Sample 1 (oxide semiconductor layer 140 containing Poly-OS) is hardly etched using the mixed acid etching solution, and is etched at only 2 nm/min at most even when 0.5% of the hydrofluoric acid solution is used. When etching using the mixed acid etching solution, the etching rate of Sample 1 is less than or equal to 1/100 of the etching rate of Sample 2 (oxide semiconductor film having an amorphous structure before the heat treatment). When etching using 0.5% of the hydrofluoric acid solution, the etching rate of Sample 1 is less than or equal to approximately 1/10 of the etching rate of Sample 2. Further, when etching using the mixed acid etching solution, the etching rate of Sample 1 is less than or equal to 1/100 of the etching rate of Sample 3 (oxide semiconductor film containing IGZO in which the ratio of indium is less than 50%). That is, Sample 1 has significantly better etching resistance than Samples 2 and 3.

Such an excellent etching resistance of the oxide semiconductor layer 140 containing the Poly-OS is a characteristic that cannot be obtained with the conventional oxide semiconductor having a polycrystalline structure, which is manufactured by a process lower than or equal to 500° C. Although the detailed mechanism of the excellent etching resistance of the oxide semiconductor layer 140 containing the Poly-OS is unclear, it is considered that the Poly-OS has a polycrystalline structure different from that of a conventional oxide semiconductor.

As described above, the oxide semiconductor layer 140 containing the Poly-OS has a very low etching rate with respect to an etching solution. Therefore, it is very difficult to pattern the oxide semiconductor layer 140. Thus, when the oxide semiconductor layer 140 is formed in an island shape, the oxide semiconductor film having an amorphous structure before the heat treatment is patterned in an island shape, and then the oxide semiconductor film is crystallized by performing the heat treatment. In this way, the island-shaped oxide semiconductor layer 140 containing the Poly-OS can be formed.

### [2-3. Structure of Oxide Semiconductor Layer 140]

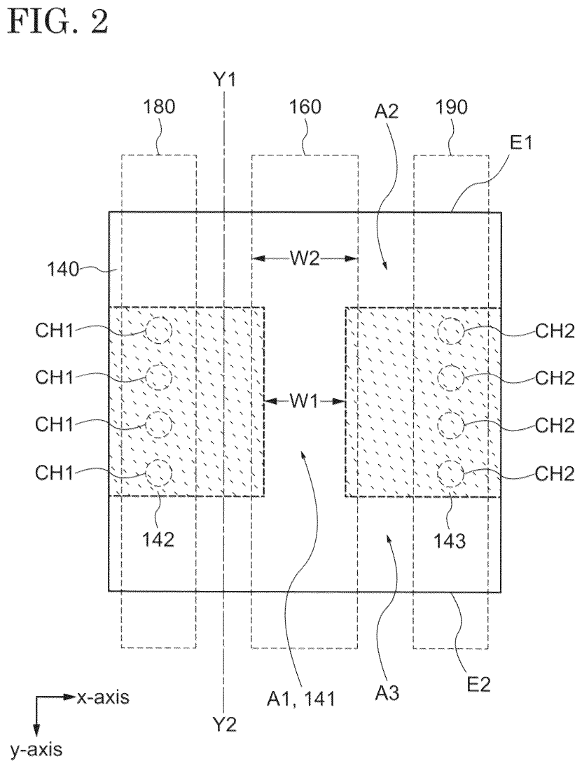

FIG. 2 is a schematic plan view showing a configuration of the oxide semiconductor layer 140 of the semiconductor device 10 according to an embodiment of the present invention. For convenience of explanation, the gate electrode 160, the source electrode 180, and the drain electrode 190 located over the oxide semiconductor layer 140 are shown by dotted lines in FIG. 2.

The oxide semiconductor layer 140 is formed in an island shape. Although the planar shape of the oxide semiconductor layer 140 is a quadrangle, the planar shape is not limited thereto. Since the oxide semiconductor layer 140 is formed in an island shape, the oxide semiconductor layer 140 has one or more edges. As shown in FIG. 2, when the planar shape of the oxide semiconductor layer 140 is a quadrangle, the oxide semiconductor layer 140 has four edges.

As shown in FIG. 2, the oxide semiconductor layer 140 includes a channel region 141, a source region 142, and a drain region 143. The channel region 141 is located between the source region 142 and the drain region 143. The channel region 141 overlaps the gate electrode 160. The source region 142 overlaps the source electrode 180. The drain region 143 overlaps the drain electrode 190. The source electrode 180 is electrically connected to the source region 142 through contact holes CH1, and the drain electrode 190 is electrically connected to the drain region 143 through contact holes CH2. The channel region 141 has properties of a semiconductor. Therefore, when a voltage is applied to the gate electrode 160, a channel that becomes a current path is formed in the channel region 141. Each of the source region 142 and the drain region 143 has properties of a conductor. Therefore, the carrier concentrations of the source region 142 and the drain region 143 are higher than the carrier concentration of the channel region 141. In other words, the channel region 141 has a higher electrical resistivity (or a lower electrical conductivity) than each of the source region 142 and the drain region 143. For example, the sheet resistances of the source region 142 and the drain region 143 are less than or equal to 1000 Ω/sq., preferably less than or equal to 500 Ω/sq., and more preferably less than or equal to 250 Ω/sq. In the following description, a region such as the channel region 141 having a higher electrical resistivity than the source region 142 and the drain region 143 is referred to as a “high resistance region”, for convenience of explanation.

The oxide semiconductor layer 140 includes a first region A1, a second region A2, and a third region A3 as high resistance regions. The first region A1 is located between the source region 142 and the drain region 143. That is, the first region A1 is a channel region 141. The second region A2 includes a first edge E1 extending along an x-axis direction of the oxide semiconductor layer 140 and is adjacent to the first region A1. The third region A3 includes a second edge E2 extending along the x-axis direction of the oxide semiconductor layer 140 and is adjacent to the first region A1. The second edge E2 is located on the opposite side of the first edge E1. That is, the third region A3 is located on the opposite side of the second region A2 with the first region A1 interposed therebetween. In a plan view, each of the source region 142 and the drain region 143 is surrounded by the first region A1 to the third region A3.

In the plan view, the gate electrode 160 extends so as to overlap the first region A1, the second region A2, and the third region A3, and covers the entire first region A1. The gate electrode 160 also overlaps a part of the source region 142 and a part of the drain region 143. Therefore, a first width W1 of the first region A1 in the x-axis direction (corresponding to the channel length of the channel region 141) is smaller than a second width W2 of the gate electrode 160 in the x-axis direction.

### [2-4. Formation of Source Region 142 and Drain Region 143]

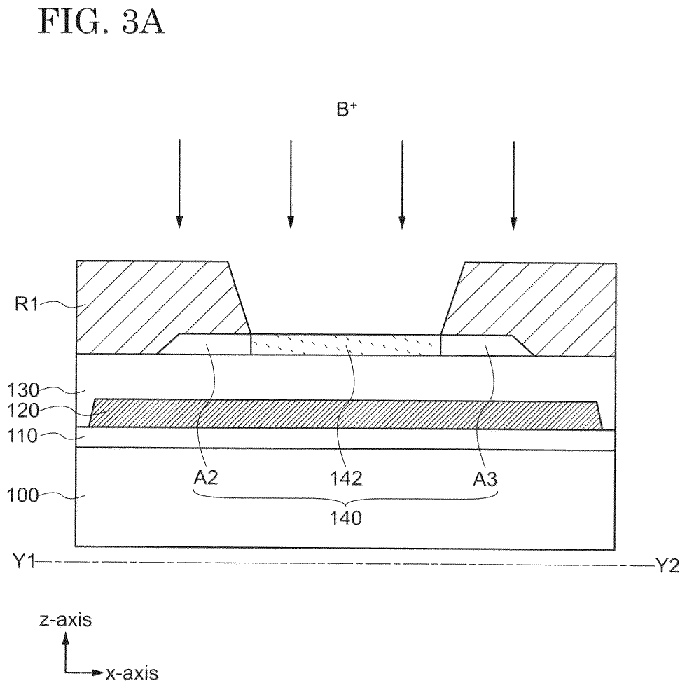

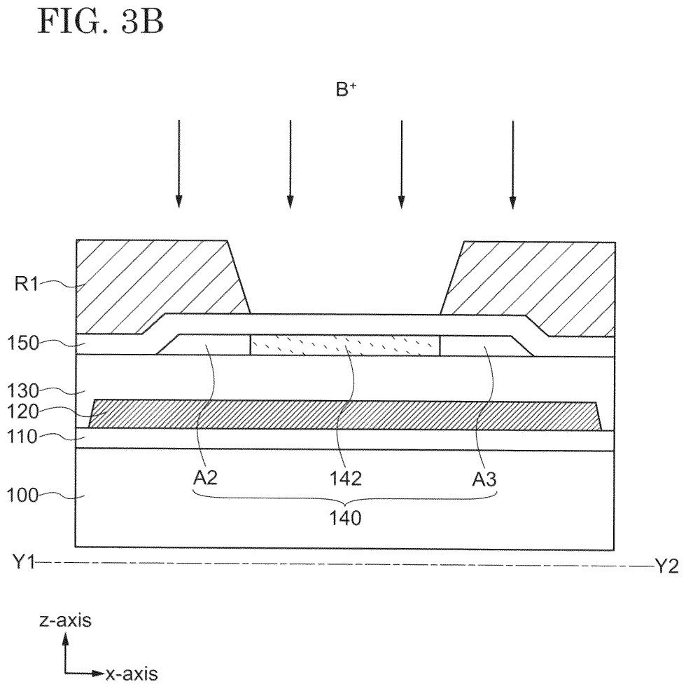

FIGS. 3A and 3B are schematic cross-sectional views showing a method for forming the source region 142 and the drain region 143 in the oxide semiconductor layer 140 of the semiconductor device 10 according to an embodiment of the present invention. Specifically, each of FIG. 3A and FIG. 3B is a cross-sectional view cut along a line Y1-Y2 in FIG. 2.

FIG. 3A shows the oxide semiconductor layer 140 formed on the second insulating layer 130 using the above-described Poly-OS technique. Therefore, the oxide semiconductor layer 140 in FIG. 3A has a predetermined shape and contains Poly-OS. In the method for forming the source region 142 and the drain region 143 shown in FIG. 3A, a resist R1 having a desired shape is formed on the oxide semiconductor layer 140. The resist R1 overlaps regions in which high resistance regions (the first region A1, the second region A2, and the third region A3) are to be formed. On the other hand, the resist R1 does not overlap regions in which the source region 142 and the drain region 143 are to be formed.

Next, an impurity element is doped into the oxide semiconductor layer 140 using the resist R1 as a mask. In one example, the oxide semiconductor layer 140 is doped with boron (B) as an impurity element by ion implantation. In addition, instead of boron, another impurity element such as phosphorus (P) may be doped into the oxide semiconductor layer 140. As a result, the source region 142 and the drain region 143 doped with the impurity element are formed in the oxide semiconductor layer 140. Since oxygen deficiencies are formed in the source region 142 and the drain region 143 by the doping of the impurity element, the source region 142 and the drain region 143 have low resistance. On the other hand, the high resistance region not containing the impurity element is also formed by being masked with the resist R1. In addition, in the oxide semiconductor layer 140 including Poly-OS, the source region 142 and the drain region doped with the impurity element may have crystallinity, which is also one of the characteristics of Poly-OS. In this case, the crystal structure of each of the source region 142 and the drain region 143 is the same as the crystal structure of the channel region 141.

Next, after removing the resist R1, a silicon oxide film is deposited to form the gate insulating layer 150. Then, the gate electrode 160 is formed on the gate insulating layer 150. At this time, the gate electrode 160 is patterned so as to overlap the first region A1.

FIG. 3B shows a method for forming the source region 142 and the drain region 143 that is different from that shown in FIG. 3A. FIG. 3B shows the gate insulating layer 150 formed on the oxide semiconductor layer 140 containing Poly-OS. In the method for forming the source region 142 and the drain region 143 shown in FIG. 3B, a resist R1 having a desired shape is formed on the gate insulating layer 150. The resist R1 overlaps a region in which a high resistance region is to be formed. On the other hand, the resist R1 does not overlap a region in which the source region 142 and the drain region 143 are to be formed.

Next, using the resist R1 as a mask, an impurity element is doped into the oxide semiconductor layer 140 through the gate insulating layer 150. As a result, the source region 142 and the drain region 143 doped with the impurity element are formed in the oxide semiconductor layer 140.

Next, after removing the resist R1, the gate electrode 160 is formed on the gate insulating layer 150. At this time, the gate electrode 160 is patterned so as to overlap the first region A1.

In the method for forming the source region 142 and the drain region 143 shown in FIGS. 3A and 3B, the doping of the impurity element into the oxide semiconductor layer 140 is performed using the resist R1 as a mask, not the gate electrode 160 as a mask. Therefore, as shown in FIG. 2, the second width W2 of the gate electrode 160 is not necessarily the same as the first width W1 of the first region A1. Further, the second width W2 is set to be larger than the first width W1 so that the gate electrode 160 overlaps the entire first region A1. Therefore, the gate electrode 160 overlaps not only the entire first region A1 but also a part of the source region 142 and a part of the drain region 143. Further, the gate electrode 160 also overlaps a part of the second region A2 and a part of the third region A3.

In the semiconductor device 10 manufactured using the method for forming the source region 142 and the drain region 143 shown in FIG. 3A or 3B, the second region A2 including the first edge E1 and the third region A3 including the second edge E2 have a similar high resistance to the first region A1 corresponding to the channel region 141. Therefore, the second region A2 and the third region A3 cannot become a current path like the source region 142 and the drain region 143. That is, when a gate voltage equal to or higher than the threshold value is applied to the gate electrode 160, a current flows between the source electrode 180 and the drain electrode 190 through the channel region 141, the source region 142, and the drain region 143 in the oxide semiconductor layer 140. On the other hand, almost no current flows through the second region A2 and the third region A3 in the oxide semiconductor layer 140.

The second region A2 including the first edge E1 and the third region A3 including the second edge E2 are regions that are easily damaged by etching when forming the oxide semiconductor layer 140 with an island shape and are easily deteriorated due to heat generation caused by current flow. In the present embodiment, since heat generation in the second region A2 and the third region A3 is reduced, deterioration due to heat generation in the second region A2 and the third region A3 can be suppressed. Therefore, increasing the resistance of the second region A2 and the third region A3 to make it difficult for current to flow is effective in suppressing deterioration of the second region A2 and the third region A3.

Further, even when the second region A2 and the third region A3 are deteriorated, the second region A2 and the third region A3 are not regions in which a current path is originally formed, so that the influence on the electrical characteristics of the semiconductor device 10 is small. Specifically, a shift in the threshold voltage is suppressed in the semiconductor device 10. Therefore, the semiconductor device 10 can have high reliability.

### Modification 1

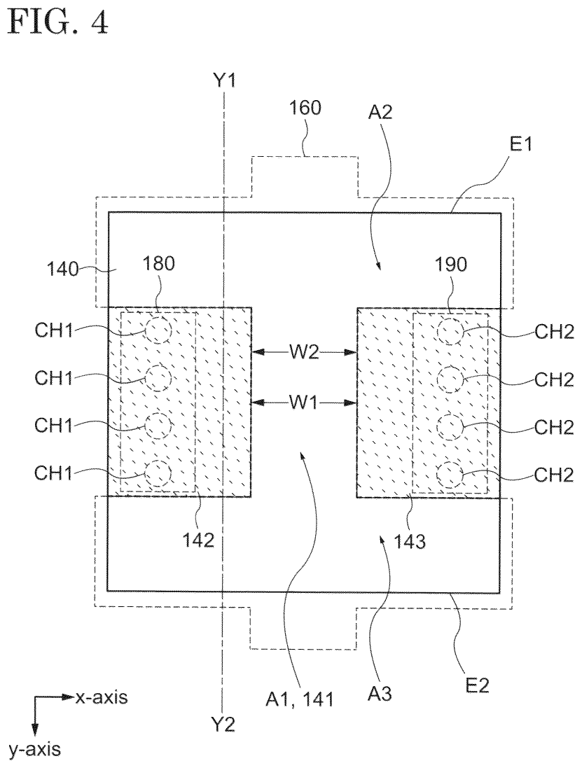

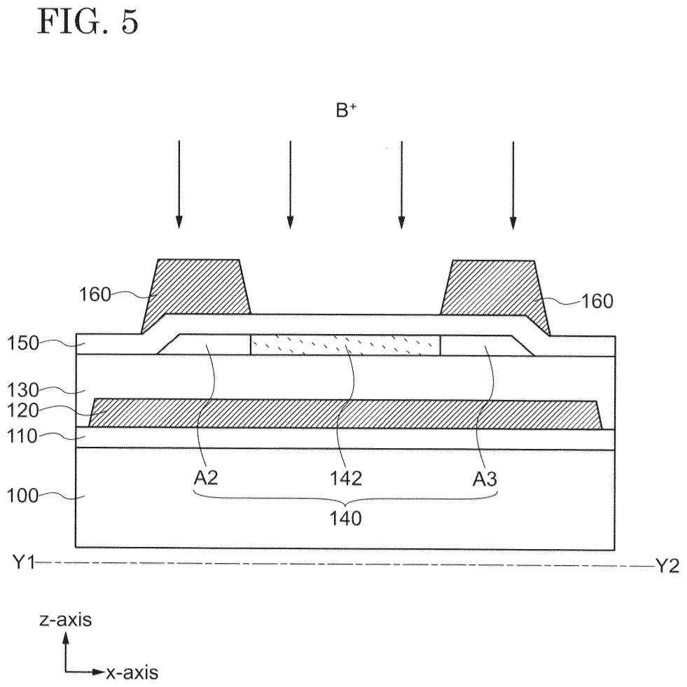

A modification of the present embodiment is described with reference to FIGS. 4 and 5. In addition, the description of the configuration similar to the above-described configuration may be omitted in the following description.

FIG. 4 is a schematic plan view showing a configuration of an oxide semiconductor layer 140 of the semiconductor device 10 according to a modification of an embodiment of the present invention. For convenience of explanation, a gate electrode 160, a source electrode 180, and a drain electrode 190 located over the oxide semiconductor layer 140 are shown by dotted lines in FIG. 4.

The shapes of the first region A1 to the third region A3, the source region 142, and the drain region 143 in the oxide semiconductor layer 140 are as described with reference to FIG. 2. In the oxide semiconductor layer 140 shown in FIG. 4, the first width W1 of the first region A1 in the x-axis direction is substantially the same as the second width W2 of the gate electrode 160 in the x-axis direction. The gate electrode 160 overlaps not only the entire first region A1, but also the entire second region A2 and the entire third region A3. In a plan view, the boundary between the first region A1 to the third region A3 and the source region 142 substantially coincides with the edge of the gate electrode 160. Similarly, the boundary between the first region A1 to the third region A3 and the drain region 143 substantially coincides with the edge of the gate electrode 160.

In the plan view, although the source electrode 180 overlaps the source region 142, the source electrode 180 does not overlap the first region A1 to the third region A3. Similarly, although the drain electrode 190 overlaps the drain region 143, the drain electrode 190 does not overlap the first region A1 to the third region A3. The source electrode 180 is in contact with the source region 142 through contact holes CH1, and the drain electrode 190 is in contact with the drain region 143 through contact holes CH2.

FIG. 5 is a schematic cross-sectional view showing a method for forming the source region 142 and the drain region 143 in the oxide semiconductor layer 140 of the semiconductor device 10 according to a modification of an embodiment of the present invention. Specifically, FIG. 5 is a cross-sectional view cut along a line Y1-Y2 in FIG. 4.

FIG. 5 shows the gate insulating layer 150 formed on the oxide semiconductor layer 140 containing Poly-OS. In the formation method shown in FIG. 5, the gate electrode 160 having a desired shape is formed on the gate insulating layer 150. The gate electrode 160 overlaps regions in which high-resistance regions (the first region A1, the second region A2, and the third region A3) are to be formed. On the other hand, the gate electrode 160 does not overlap regions in which the source region 142 and the drain region 143 are to be formed.

Next, the impurity element is doped into the oxide semiconductor layer 140 through the gate insulating layer 150 using the gate electrode 160 as a mask. As a result, the source region 142 and the drain region 143 doped with the impurity element are formed in the oxide semiconductor layer 140.

In the method for forming the source region 142 and the drain region 143 shown in FIG. 5, the doping of the impurity element into the oxide semiconductor layer 140 is performed using the gate electrode 160 as a mask. Therefore, as shown in FIG. 4, the second width W2 of the gate electrode 160 is substantially the same as the first width W1 of the first region A1. Although the gate electrode 160 does not overlap the source region 142 and the drain region 143, the gate electrode overlaps the entire second region A2 and the entire third region A3.

The semiconductor device 10 described with reference to FIGS. 4 and 5 also provides the same effects as those described above.

### Modification 2

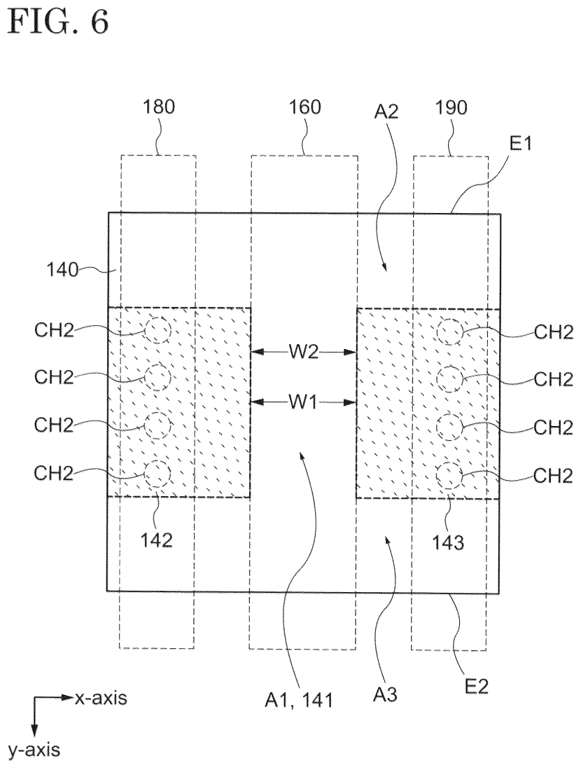

Another modification of the present embodiment is described with reference to FIG. 6. In addition, the description of the configuration similar to the above-described configuration may be omitted in the following.

FIG. 6 is a schematic plan view showing a configuration of an oxide semiconductor layer 140 of the semiconductor device 10 according to a modification of an embodiment of the present invention. For convenience of explanation, a gate electrode 160, a source electrode 180, and a drain electrode 190 located over the oxide semiconductor layer 140 are shown by dotted lines in FIG. 6.

The shapes of the first region A1 to the third region A3, the source region 142, and the drain region 143 in the oxide semiconductor layer 140 are as described with reference to FIG. 2. In the oxide semiconductor layer 140 shown in FIG. 6, the first width W1 of the first region A1 in the x-axis direction is substantially the same as the second width W2 of the gate electrode 160 in the x-axis direction. Although the gate electrode 160 overlaps the entire first region A1, the gate electrode 160 overlaps a part of the second region A2 and a part of the third region A3. That is, the gate electrode 160 extends with the second width W2 along a y-axis direction and overlaps the second region A2 and the third region A3.

In a plan view, the source electrode 180 overlaps the second region A2, the third region A3, and the source region 142. The drain electrode 190 overlaps the second region A2, the third region A3, and the drain region 143. However, the source electrode 180 and the drain electrode 190 are not in contact with the second region A2 and the third region A3. The source electrode 180 in contact with the source region 142 through contact holes CH1, and the drain electrode 190 is in contact with the drain region 143 through contact holes CH2.

The shape of the gate electrode 160 shown in FIG. 6 can be formed, for example, as in the following description. That is, as described with reference to FIG. 5, the gate electrode 160 is patterned so as to overlap regions of the oxide semiconductor layer 140 in which high resistance regions (the first region A1 to the third region) are to be formed. Then, the impurity element is doped into the oxide semiconductor layer 140 using the gate electrode 160 as a mask. Then, parts of the gate electrode 160 that overlap portions adjacent to the source region 142 and the drain region 143 of the second region A2 and the third region A3 are removed by etching. In this way, the gate electrode 160 having the shape shown in FIG. 6 is formed.

The semiconductor device 10 described with reference to FIG. 6 can also achieve the same effects as those described above.

### Modification 3

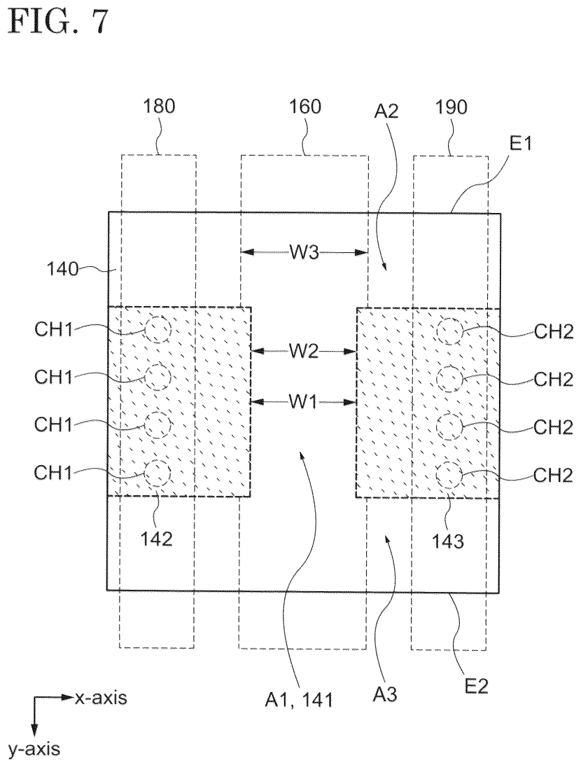

Another modification of the present embodiment is described with reference to FIG. 7. In addition, the description of the configuration similar to the above-described configuration may be omitted in the following.

FIG. 7 is a schematic plan view showing a configuration of an oxide semiconductor layer 140 of the semiconductor device 10 according to a modification of an embodiment of the present invention. For convenience of explanation, a gate electrode 160, a source electrode 180, and a drain electrode 190 located over the oxide semiconductor layer 140 are shown by dotted lines in FIG. 7.

The shapes of the first region A1 to the third region A3, the source region 142, and the drain region 143 in the oxide semiconductor layer 140 are as described with reference to FIG. 2. In the oxide semiconductor layer 140 shown in FIG. 7, the gate electrode 160 has a second width W2 and a third width W3 in the x-axis direction and extends in the y-axis direction. The portion of the gate electrode 160 overlapping the first region A1 has the second width W2. The portion of the gate electrode 160 overlapping the second region A2 and the third region A3 has the third width W3. The second width W2 is substantially the same as the first width W1. On the other hand, the third width W3 is larger than the first width W1.

The shape of the gate electrode 160 shown in FIG. 7 can be formed, for example, as in the following description. That is, as described with reference to FIG. 5, the gate electrode 160 is patterned so as to overlap regions of the oxide semiconductor layer 140 in which high resistance regions (the first region A1 to the third region) are to be formed. Then, parts of the gate electrode 160 are removed by etching. At this time, the gate electrode 160 is etched so that the widths of the portions overlapping the second region A2 and the third region A3 are larger than the width of the portion overlapping the first region A1. In this way, the gate electrode 160 having the shape shown in FIG. 7 is formed.

The semiconductor device 10 described with reference to FIG. 7 can also achieve the same effects as those described above.

### Modification 4

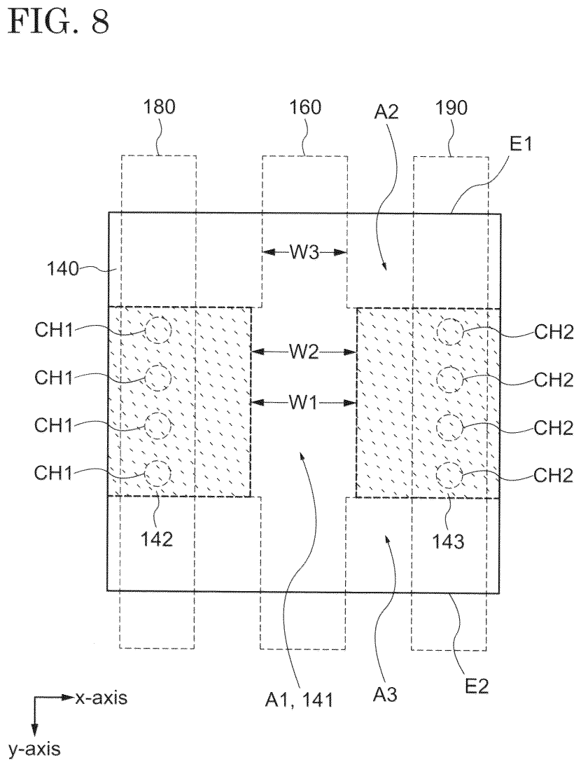

Another modification of the present embodiment is described with reference to FIG. 8. In addition, the description of the configuration similar to the above-described configuration may be omitted in the following description.

FIG. 8 is a schematic plan view showing a configuration of an oxide semiconductor layer 140 of the semiconductor device 10 according to a modification of an embodiment of the present invention. For convenience of explanation, a gate electrode 160, a source electrode 180, and a drain electrode 190 located over the oxide semiconductor layer 140 are shown by dotted lines in FIG. 8.

The shapes of the first region A1 to the third region A3, the source region 142, and the drain region 143 in the oxide semiconductor layer 140 are as described with reference to FIG. 2. In the oxide semiconductor layer 140 shown in FIG. 7, the gate electrode 160 has a second width W2 and a third width W3 in the x-axis direction and extends in the y-axis direction. The portion of the gate electrode 160 overlapping the first region A1 has the second width W2. The portion of the gate electrode 160 overlapping the second region A2 and the third region A3 has the third width W3. The second width W2 is substantially the same as the first width W1. On the other hand, the third width W3 is smaller than the first width W1.

The shape of the gate electrode 160 shown in FIG. 7 can be formed, for example, as in the following description. That is, as described with reference to FIG. 5, the gate electrode 160 is patterned so as to overlap regions of the oxide semiconductor layer 140 in which high resistance regions (the first region A1 to the third region) are to be formed. Then, parts of the gate electrode 160 are removed by etching. At this time, the gate electrode 160 is etched so that the widths of the portions overlapping the second region A2 and the third region A3 are smaller than the width of the portion overlapping the first region A1. In this way, the gate electrode 160 having the shape shown in FIG. 8 is formed.

The semiconductor device 10 described with reference to FIG. 8 can also achieve the same effects as those described above.

### Modification 5

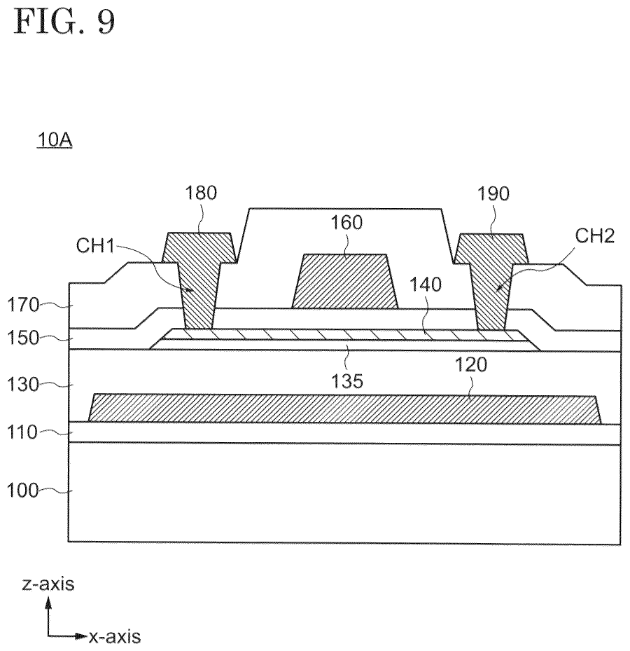

Another modification of the present embodiment is described with reference to FIG. 9. In addition, the description of the configuration similar to the above-described configuration may be omitted in the following description.

FIG. 9 is a schematic plan view showing a configuration of a semiconductor device 10A according to a modification of an embodiment of the present invention.

As shown in FIG. 9, the semiconductor device 10A includes the substrate 100, the first insulating layer 110, the light shielding layer 120, the second insulating layer 130, a metal oxide layer 135, the oxide semiconductor layer 140, the gate insulating layer 150, the gate electrode 160, the third insulating layer 170, the source electrode 180, and the drain electrode 190. In the semiconductor device 10A, the metal oxide layer 135 is provided under and in contact with the oxide semiconductor layer 140. An edge surface of the metal oxide layer 135 is substantially aligned with the edge surface of the oxide semiconductor layer 130. The gate insulating layer 150 is provided on the second insulating layer 130 so as to cover the edge surface of the metal oxide layer 135 and the upper surface and the edge surface of the oxide semiconductor layer 140.

The metal oxide layer 135 can function as a buffer layer that improves the crystallinity of the oxide semiconductor layer 140. In the semiconductor device 10A including the oxide semiconductor layer 140 with improved crystallinity, the field effect mobility is further improved.

A metal oxide containing aluminum as a main component is used for the metal oxide layer 135. The ratio of aluminum contained in the metal oxide layer 135 may be greater than or equal to 5% and less than or equal to 70%, greater than or equal to 10% and less than or equal to 60%, or greater than or equal to 30% and less than or equal to 50% of the entire metal oxide layer 135. The above ratio may be a mass ratio or a weight ratio.

The thickness of the metal oxide layer 135 is greater than or equal to 1 nm and less than or equal to 10 nm, preferably greater than or equal to 1 nm and less than or equal to 5 nm. It is preferable that aluminum oxide is used for the metal oxide layer 135. Aluminum oxide has high barrier properties against gases such as oxygen and hydrogen. Here, the barrier properties refer to a function of suppressing the permeation of gases such as oxygen and hydrogen.

In addition, a metal oxide containing a metal other than aluminum as a main component may be used for the metal oxide layer 135. For example, indium tin oxide (ITO), indium zinc oxide (IZO), indium gallium zinc oxide (IGZO), or the like can be used for the metal oxide layer 135.

The metal oxide layer 135 can be deposited by a sputtering method or an atomic layer deposition method (ALD method). Further, the metal oxide layer 135 can be patterned using the oxide semiconductor layer 140 as a mask. As described above, the oxide semiconductor layer 140 containing Poly-OS has excellent etching resistance. Therefore, even when the metal oxide layer 135 is etched in the patterning of the metal oxide layer 135, the oxide semiconductor layer 140 used as a mask is not etched. In the semiconductor device 10A, the oxide semiconductor layer 140 can be used as a mask in the formation of the metal oxide layer 135, so that a photolithography process can be omitted.

The semiconductor device 10A described with reference to FIG. 9 can also achieve the same effects as those described above. Further, since the oxide semiconductor layer 140 is formed using the metal oxide layer 135 as a buffer layer in the semiconductor device 10A, the crystallinity of the oxide semiconductor layer 140 containing Poly-OS is improved. As a result, the semiconductor device 10A has a higher field-effect mobility.

### Second Embodiment

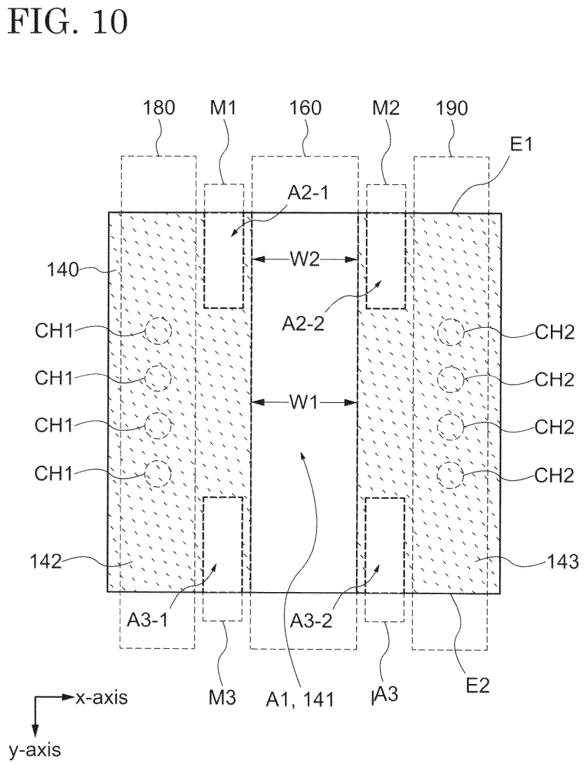

A semiconductor device 10 according to an embodiment of the present invention is described with reference to FIG. 10. In addition, the description of the configuration similar to the configuration in the First Embodiment may be omitted in the following description.

FIG. 10 is a schematic plan view showing a configuration of an oxide semiconductor layer 140 of the semiconductor device 10 according to an embodiment of the present invention. For convenience of explanation, a gate electrode 160, a source electrode 180, and a drain electrode 190 located above the oxide semiconductor layer 140 are shown by dotted lines in FIG. 10.

The oxide semiconductor layer 140 shown in FIG. 10 includes high-resistance regions (a first region A1, a second-1 region A2-1, a second-2 region A2-2, a third-1 region A3-1, and a third-2 region A3-2), a source region 142, and a drain region 143. The first region A1 is located between the source region 142 and the drain region 143. The second-1 region A2-1 includes a part of a first edge E1 and is located in the source region 142. The second-2 region A2-2 includes a part of the first edge E1 and is located in the drain region 143. The third-1 region A3-1 includes a part of a second edge E2 and is located in the source region 142. The third-2 region A3-2 includes a part of the second edge E2 and is located in the drain region. In other words, the second-1 region A2-1 and the third-1 region A3-1 are surrounded by the source region 142, and the second-2 region A2-2 and the third-2 region A3-2 are surrounded by the drain region 143.

The gate electrode 160 overlaps the entire first region A1 and extends in the y-axis direction. A first width W1 of the first region A1 in the x-axis direction is substantially the same as a second width W2 of the gate electrode 160 in the x-axis direction. In the present embodiment, a first metal layer M1, a second metal layer M2, a third metal layer M3, and a fourth metal layer M4 are provided as the same layer as the gate electrode 160. That is, the gate electrode 160 and the first to fourth metal layers M1 to M4 can be formed commonly in the same process. The first to fourth metal layers M1 to M4 have an island shape. The first metal layer M1, the second metal layer M2, the third metal layer M3, and the fourth metal layer M4 overlap the entire second-1 region A2-1, the entire second-2 region A2-2, the entire third-1 region A3-1, and the entire third-2 region A3-2, respectively.

In a plan view, the second-1 region A2-1 and the third-1 region A3-1 are located between the gate electrode 160 and the source electrode 180. The second-2 region A2-2 and the third-2 region A3-2 are located between the gate electrode 160 and the drain electrode 190. The source electrode 180 is in contact with the source region 142 through contact holes CH1, and the drain electrode 190 is in contact with the drain region 143 through contact holes CH2.

The first metal layer M1 to the fourth metal layer M4 do not overlap the gate electrode 160, the source electrode 180, and the drain electrode 190. Therefore, although the first metal layer M1 to the fourth metal layer M4 are electrically floating, the first metal layer M1 to the fourth metal layer M4 are hardly affected by the potential of any of the gate electrode 160, the source electrode 180, and the drain electrode 190.

The high resistance regions, the source region 142, and the drain region 143 of the oxide semiconductor layer 140 shown in FIG. 10 are formed by doping the impurity element into the oxide semiconductor layer 140 using the gate electrode 160 and the first to fourth metal layers M1 to M4 as a mask. In addition, the first to fourth metal layers M1 to M4 may be removed after the ion implantation.

In the semiconductor device 10 described with reference to FIG. 10, the second-1 region A2-1 and the second-2 region A2-2 that have a high resistance are provided so as to include the first edge E1, and the third-1 region A3-1 and the third-2 region A3-2 that have a high resistance are provided so as to include the second edge E2. Thus, the channel region 141 is formed in the center of the first region A1 away from the first edge E1 and the second edge E2, and no current path is formed in the vicinity of the first edge E1 and the vicinity of the second edge E2. Therefore, the semiconductor device 10 described with reference to FIG. 10 also has the same effect as the First Embodiment.

### Third Embodiment

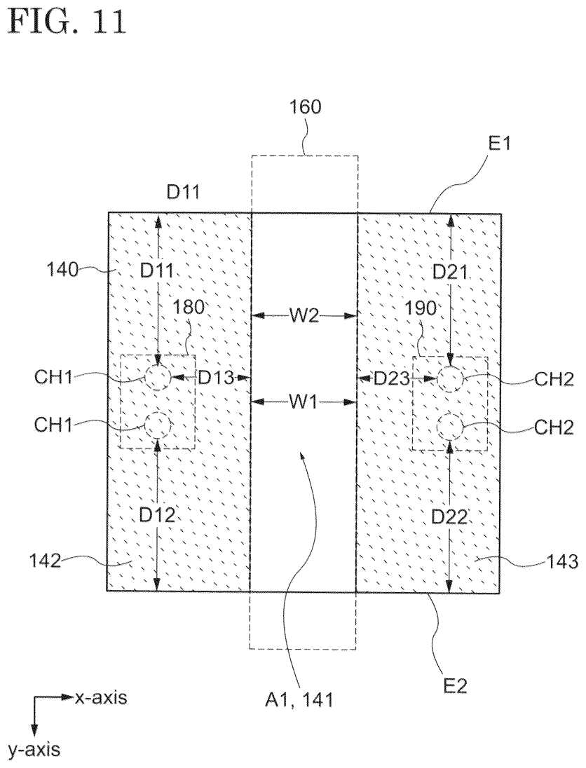

A semiconductor device 10 according to an embodiment of the present invention is described with reference to FIG. 11. In addition, the description of the configuration similar to the configuration in the First Embodiment or the Second Embodiment may be omitted in the following description.

FIG. 11 is a schematic plan view showing a configuration of an oxide semiconductor layer 140 of the semiconductor device 10 according to an embodiment of the present invention. For convenience of explanation, a gate electrode 160, a source electrode 180, and a drain electrode 190 located above the oxide semiconductor layer 140 are shown by dotted lines in FIG. 11.

The oxide semiconductor layer 140 shown in FIG. 11 includes a high resistance region (a first region A1), a source region 142, and a drain region 143. The first region A1 is located between the source region 142 and the drain region 143. In the present embodiment, the oxide semiconductor layer 140 does not include the second region A2 and the third region A3 that have a high resistance described in the First Embodiment.

In a plan view, the source electrode 180 overlaps the oxide semiconductor layer 140 at a position approximately midway between a first edge E1 and a second edge E2, and is in contact with the source region 142 through contact holes CH1. A distance D11 from the first edge E1 to one of the contact holes CH1 along the y-axis direction is substantially the same as a distance D12 from the second edge E2 to another of the contact holes CH1 along the y-axis direction. A distance D13 from the first region A1 to one of the contact holes CH1 along the x-axis direction is smaller than the distance D11 and the distance D12. In one example, the distance D11 and the distance D12 are greater than or equal to twice the distance D13.

In a plan view, the drain electrode 190 overlaps the oxide semiconductor layer 140 at a position approximately midway between the first edge E1 and the second edge E2, and is in contact with the drain region 143 through contact holes CH2. A distance D21 from the first edge E1 to one of the contact holes CH1 along the y-axis direction is approximately equal to a distance D22 from the second edge E2 to another of the contact holes CH2 along the y-axis direction. A distance D23 from the first region A1 to one of the contact holes CH2 along the x-axis direction is smaller than the distance D21 and the distance D22. In one example, the distances D21 and D22 are greater than or equal to twice the distance D23.

In the semiconductor device 10 described with reference to FIG. 11, when a gate voltage equal to or higher than a threshold value is applied to the gate electrode 160, the electric field lines between the source electrode 180 and the drain electrode 190 are concentrated in the central portion of the oxide semiconductor layer 140, while the electric field lines are unlikely to spread to the vicinity of the first edge E1 and the vicinity of the second edge E2. Thus, the channel region 141 is formed in the central portion of the first region A1 away from the first edge E1 and the second edge E2, and no current path is formed in the vicinity of the first edge E1 and the vicinity of the second edge E2. Therefore, the semiconductor device 10 described with reference to FIG. 11 also has the same effect as the First Embodiment.

### Modification

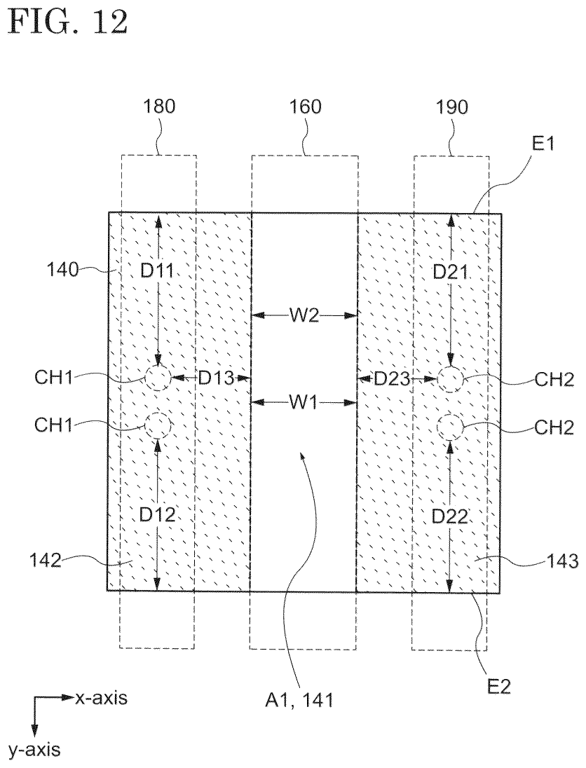

A modification of the present embodiment is described with reference to FIG. 12. In addition, the description of the configuration similar to the above-described configuration may be omitted in the following description.

FIG. 12 is a schematic plan view showing a configuration of an oxide semiconductor layer 140 of the semiconductor device 10 according to a modification of an embodiment of the present invention. For convenience of explanation, a gate electrode 160, a source electrode 180, and a drain electrode 190 located over the oxide semiconductor layer 140 are shown by dotted lines in FIG. 12.

In the oxide semiconductor layer 140 shown in FIG. 12, the source electrode 180 and the drain electrode 190 extend in the y-axis direction, and overlap the first edge E1 and the second edge E2. However, the source electrode 180 is in contact with the source region 142 through contact holes CH1 formed at a position sufficiently distant from the first edge E1 and the second edge E2, as in the configuration shown in FIG. 11. The drain electrode 190 is also in contact with the drain region 143 through contact holes CH2 formed at a position sufficiently distant from the first edge E1 and the second edge E2. Therefore, the channel region 141 is formed in the center of the first region A1 away from the first edge E1 and the second edge E2, and no current path is formed in the vicinity of the first edge E1 and the vicinity of the second edge E2.

The semiconductor device 10 described with reference to FIG. 12 can also achieve the same effects as those described above.

### Fourth Embodiment

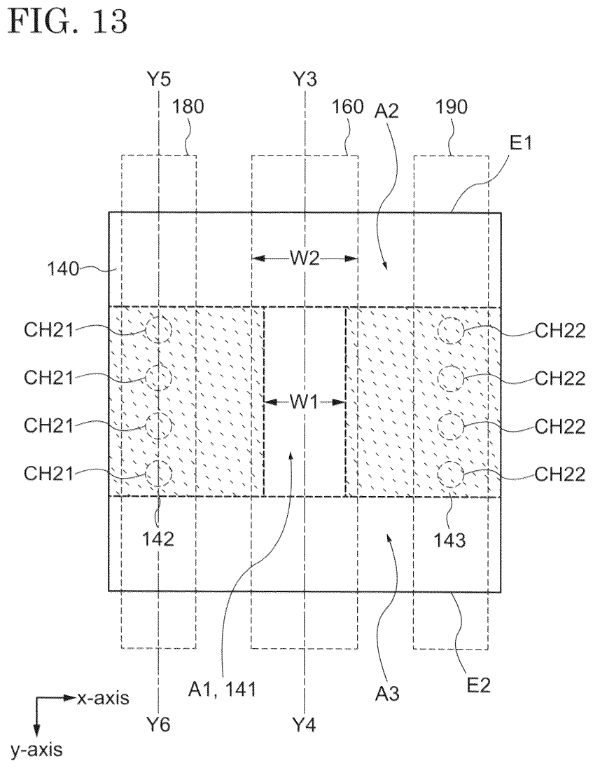

A semiconductor device 10 according to an embodiment of the present invention is described with reference to FIGS. 13 to 15C. In addition, the description of the configuration similar to the configuration in the First Embodiment to the Third Embodiment may be omitted in the following description.

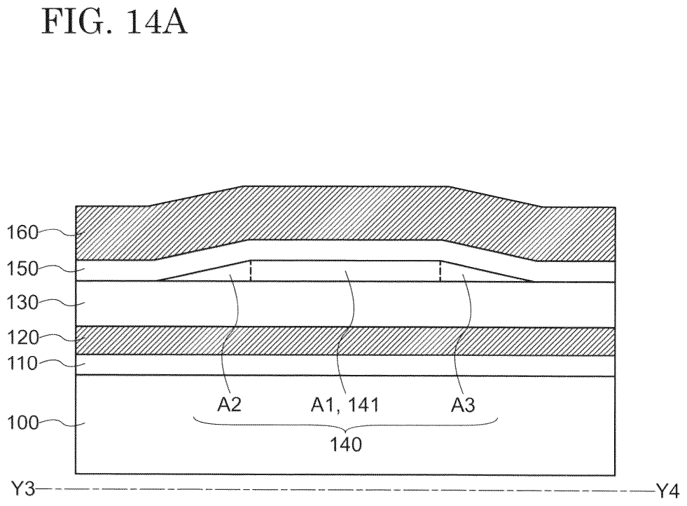

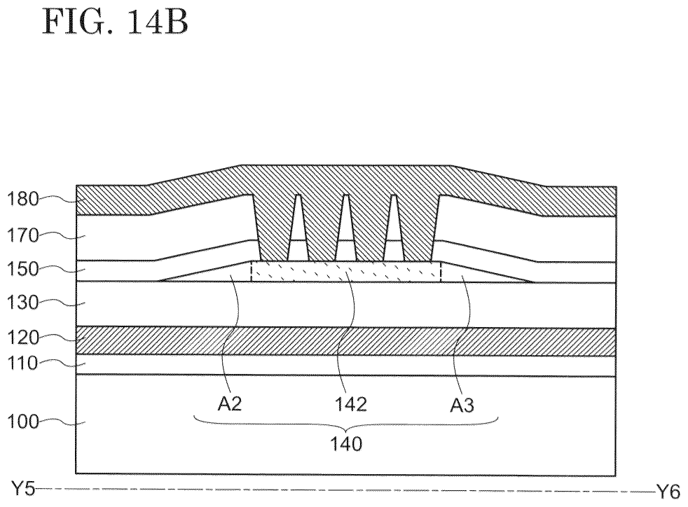

FIG. 13 is a schematic plan view showing a configuration of an oxide semiconductor layer 140 of the semiconductor device 10 according to an embodiment of the present invention. For convenience of explanation, a gate electrode 160, a source electrode 180, and a drain electrode 190 located over the oxide semiconductor layer 140 are shown by dotted lines in FIG. 13. Further, FIGS. 14A and 14B are schematic cross-sectional views showing a configuration of the semiconductor device 10 according to an embodiment of the present invention. Specifically, FIG. 14A is a cross-sectional view of the semiconductor device 10 cut along a line Y3-Y4 in FIG. 13, and FIG. 14B is a cross-sectional view cut along a line Y5-Y6 in FIG. 13.

In the oxide semiconductor layer 140 shown in FIG. 13, thicknesses of a second region A2 including a first edge E1 and a third region A3 including a second edge E2 are changed. Specifically, as shown in FIGS. 14A and 14B, the thickness of the second region A2 decreases from a first region A1 toward the first edge E1, and the thickness of the third region A3 decreases from the first region A1 toward the second edge E2. For example, widths of the second region A2 and the third region A3 in the y-axis direction are approximately 2 μm.

In a plan view, a source electrode 180 extends along the y-axis direction and overlaps the second region A2, the third region A3, and the source region 142. A source electrode 180 is not in contact with the second region A2 and the third region A3, and is in contact with the source region 142 through contact holes CH1. In the plan view, the drain electrode 190 extends along the y-axis direction and overlaps the second region A2, the third region A3, and the drain region 143. The drain electrode 190 is not contact with the second region A2 and the third region A3, and is in contact with the drain region 143 through contact holes CH2.

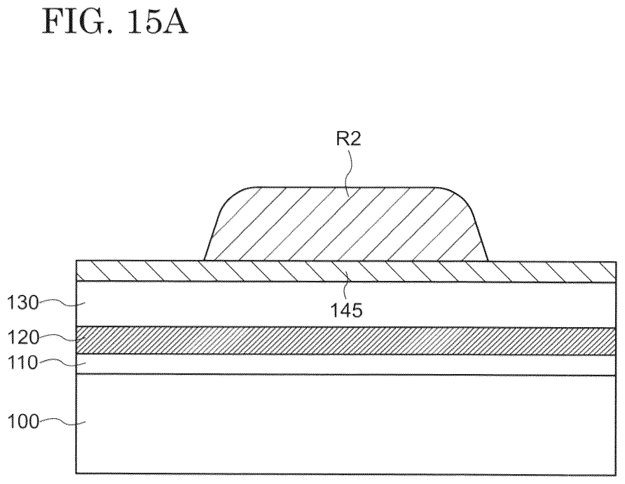

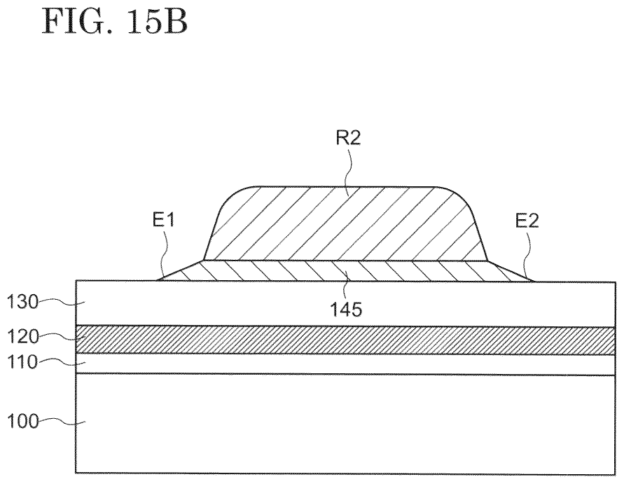

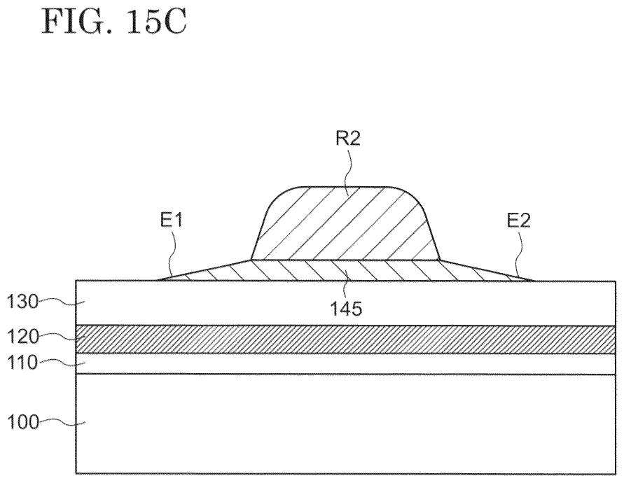

Here, one example of a method for manufacturing the oxide semiconductor layer 140 shown in FIG. 13 is described with reference to FIGS. 15A to 15C.

FIGS. 15A to 15C are schematic cross-sectional views showing a method for manufacturing the oxide semiconductor layer 140 of the semiconductor device 10 according to an embodiment of the present invention.

First, an oxide semiconductor film 145 is deposited on a second insulating layer 130. Then, a resist R2 patterned into a desired shape is formed on the oxide semiconductor film 145. Next, the oxide semiconductor film 145 is etched using the resist R2 as a mask. In this way, the oxide semiconductor film 145 with an island shape is formed.

Next, etching (or ashing) is performed. In this way, the volume of the resist R2 is reduced, and regions of the oxide semiconductor film 145 in the vicinity of the first edge E1 and the vicinity of the second edge E2 are exposed from the resist R2, so that the surface layer of the oxide semiconductor film 145 can be removed by etching.

The etching time of the region in the vicinity of the first edge E1 of the oxide semiconductor film 145 is longer than the etching time of the region overlapping the edge of the resist R2. Therefore, the thickness of the region in the vicinity of the first edge E1 is smaller than the film thickness of the region overlapping the edge of the resist R2. Similarly, the etching time of the region in the vicinity of the second edge E2 of the oxide semiconductor film 145 is longer than the etching time of the region overlapping the edge of the resist R2. Therefore, the thickness of the region in the vicinity of the second edge E2 is smaller than the thickness of the region overlapping the edge of the resist R2. On the other hand, the thickness of the central portion of the oxide semiconductor film 145 is almost unchanged even when etching is performed because the resist R2 remains so as to overlap the central portion of the oxide semiconductor film 145. In this way, the oxide semiconductor film 145 is formed whose thickness decreases toward the first edge E1 and the second edge E2.

Then, when a heat treatment is performed on the oxide semiconductor film 145 having a desired shape, the oxide semiconductor film 145 is crystallized to form the oxide semiconductor layer 140 containing Poly-OS. When the impurity element is doped into the oxide semiconductor 140 using the gate electrode 160 as a mask, the impurity element is doped into a region of the oxide semiconductor layer 140 that does not overlap the gate electrode 160. Thus, the first edge E1 included in the second region A2 and the second edge E2 included in the third region A3 are also doped with the impurity element. However, since the thicknesses in the vicinity of the first edge E1 and the vicinity of the second edge E2 are extremely small, the resistance is not reduced like the source region 142 and the drain region 143. Therefore, no current path is formed in the vicinity of the first edge E1 and the vicinity of the second edge E2. Accordingly, the semiconductor device 10 described with reference to FIG. 13 can also provide the same effect as the First Embodiment.

### Fifth Embodiment

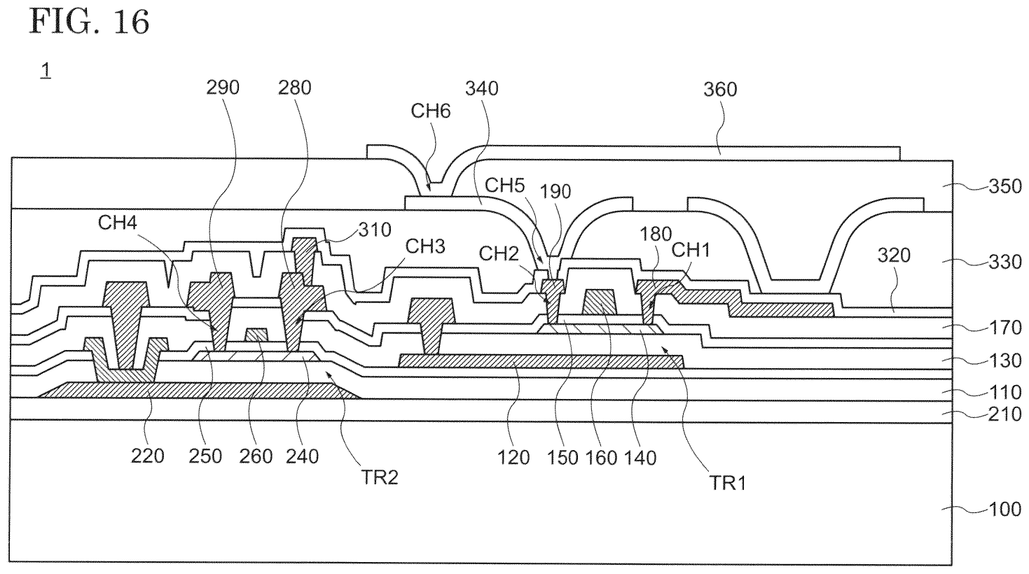

A semiconductor device 1 according to an embodiment of the present invention is described with reference to FIG. 16. In addition, the description of the configuration similar to the configuration in the First Embodiment to the Fourth Embodiment may be omitted in the following description.

FIG. 16 is a schematic cross-sectional view of the semiconductor device 1 according to an embodiment of the present invention.

The semiconductor device 1 includes a first transistor TR1 and a second transistor TR2 provided on the substrate 100. The first transistor TR1 has a similar configuration to the semiconductor device 10 described above, and includes the oxide semiconductor layer 140. The gate electrode 160 of the first transistor TR1 is electrically connected to a gate line. The source electrode 180 of the first transistor TR1 is electrically connected to a source line, a power line, or the like. The drain electrode 190 of the first transistor TR1 is electrically connected to an element electrode 360.

The second transistor TR2 includes the substrate 100, a base insulating layer 210, a light shielding layer 220, the first insulating layer 110, a silicon semiconductor layer 240, a gate insulating layer 250, a gate electrode 260, the second insulating layer 130, a source electrode 280, and a drain electrode 290. The base insulating layer 210 is provided on the substrate 100. The light shielding layer 220 is provided on the base insulating layer 210. The first insulating layer 110 is provided on the base insulating layer 210 so as to cover an upper surface and an edge surface of the light shielding layer 220. The silicon semiconductor layer 240 is provided on the first insulating layer 110. The gate insulating layer 250 is provided on the first insulating layer 110 so as to cover an upper surface and an edge surface of the silicon semiconductor layer 240. The gate electrode 260 is provided on the gate insulating layer 250 so as to overlap the silicon semiconductor layer 240. The second insulating layer 130 is provided on the gate insulating layer 250 so as to cover an upper surface and an edge surface of the gate electrode 260. An insulating layer (hereinafter, for convenience of explanation, is referred to as an “insulating layer 255”) formed of the same layer as the gate insulating layer 150 of the first transistor TR1 is provided on the second insulating layer 130. The source electrode 280 and the drain electrode 290 are provided on the insulating layer 255. The source electrode 280 is in contact with the silicon semiconductor layer 240 through a contact hole CH3 that penetrates the gate insulating layer 250, the second insulating layer 130, and the insulating layer 255. The drain electrode 290 is in contact with the silicon semiconductor layer 240 through a contact hole CH4 that penetrates the gate insulating layer 250, the second insulating layer 130, and the insulating layer 255. The source electrode 280 and the drain electrode 190 are electrically connected to the silicon semiconductor layer 240. The gate electrode 260 is electrically connected to the gate line. The source electrode 280 is electrically connected to a source line 310.

The base insulating layer 210 of the second transistor TR2 has a similar configuration to the first insulating layer 110 of the first transistor TR1. The light shielding layer 220 of the second transistor TR2 has a similar configuration to the light shielding layer 120 of the first transistor TR1. The first insulating layer 110 of the second transistor TR2 has a similar configuration to the second insulating layer 130 of the first transistor TR1.

Although a polycrystalline silicon semiconductor is used for the silicon semiconductor layer 240 of the second transistor TR2, a material of the silicon semiconductor layer 240 is not limited thereto. Other silicon-based semiconductors may also be used for the silicon semiconductor layer 240.

The gate insulating layer 250 of the second transistor TR2 has a similar configuration to the gate insulating layer 150 of the first transistor TR1. In addition, in the first transistor TR1, an insulating layer formed of the same layer as the gate insulating layer 250 is located below the light shielding layer 120 and has a similar function to the first insulating layer 110.

The gate electrode 260 of the second transistor TR2 has a similar configuration to the gate electrode 160 of the first transistor TR1. The gate electrode 260 may be electrically connected to the light shielding layer 220.

The source electrode 280 and the drain electrode 290 of the second transistor TR2 have similar configurations to the source electrode 180 and the drain electrode 190 of the first transistor TR1, respectively.

In the following description, the components included in the semiconductor device 1 other than the above-described components are described.

A connection electrode 340 is arranged on a first planarization layer 330 and is covered with a second planarization layer 350. The connection electrode 340 is in contact with the drain electrode 190 of the first transistor TR1 through a contact hole CH5 that penetrates a protective insulating layer 320 and the first planarization layer 330. Although the connection electrode 340 is a transparent electrode formed of a transparent conductive material such as indium tin oxide (ITO) or indium zinc oxide (IZO), the connection electrode 340 may also be a metal layer.

An element electrode 360 is arranged on the second planarization layer 350 and is in contact with the connection electrode 340 through a contact hole CH6 that penetrates the second planarization layer 350. The element electrode 360 is a pixel electrode, a lower electrode, an anode, or a cathode of various electronic devices. The element electrode 360 is, for example, a transparent electrode formed of a transparent conductive material such as ITO or IZO. The element electrode 360 may be a metal electrode formed of a metal material such as silver or aluminum. The element electrode 360 may also have a stacked structure of a transparent electrode and a metal electrode. For example, the element electrode 360 may have a stacked structure in which a transparent electrode, a metal electrode, and a transparent electrode are stacked in this order, or may have a stacked structure of three or more layers.

The protective insulating layer 320 can cover and protect the first transistor TR1 and the second transistor TR2. An oxide or a nitride similar to that of the first insulating layer 110 can be used for the protective insulating layer 320. The protective insulating layer 320 may have a single layer structure or a stacked layer structure.

A transparent resin such as polyimide can be used for the first planarization layer 330 and the second planarization layer 350.

The first transistor TR1 included in the semiconductor device 1 according to the present embodiment has a similar configuration to the semiconductor device 10 described in the First to Fourth Embodiments. Therefore, since deterioration of the first edge E1 and the second edge E2 of the oxide semiconductor layer 140 of the first transistor TR1 is suppressed, the semiconductor device 1 can have high reliability.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a gate electrode;
an oxide semiconductor layer having a polycrystalline structure;
a gate insulating layer between the gate electrode and the oxide semiconductor layer;
a source electrode over the oxide semiconductor layer; and
a drain electrode over the oxide semiconductor layer,
wherein the oxide semiconductor layer comprises:
a source region containing an impurity element electrically connected to the source electrode,
a drain region containing the impurity element electrically connected to the drain electrode,
a channel region between the source region and the drain region, and
a first region adjacent to the channel region, the first region comprising a first edge extending along a first direction travelling from the source region to the drain region,
the first region has a higher electrical resistivity than each of the source region and the drain region, and
an etching rate of the oxide semiconductor layer is less than 3 nm/min when the oxide semiconductor layer is etched using an etching solution containing phosphoric acid as a main component at 40° C.

2. The semiconductor device according to claim 1,
wherein the gate electrode extends in a second direction orthogonal to the first direction, and
a width of the gate electrode in the first direction is greater than a width of the channel region in the first direction.

3. The semiconductor device according to claim 1, wherein the gate electrode overlaps the entire first region.

4. The semiconductor device according to claim 1,
wherein in a plan view, the gate comprises a first portion overlapping the channel region, and
a first width of the first portion in the first direction is substantially a same as a width of the channel region in the first direction.

5. The semiconductor device according to claim 4,
wherein in the plan view, the gate further comprises a second portion overlapping the first region, and
a second width of the second portion in the first direction is greater than the first width.

6. The semiconductor device according to claim 4,
wherein in the plan view, the gate electrode further comprises a second portion overlapping the first region, and
a second width of the second portion in the first direction is less than the first width.

7. The semiconductor device according to claim 1, wherein a thickness of the first region decreases travelling from the channel region to the first edge.

8. The semiconductor device according to claim 1,
wherein the source electrode is electrically connected to the source region through a first contact hole provided in the gate insulating layer, and
the drain electrode is electrically connected to the drain region through a second contact hole provided in the gate insulating layer.

9. The semiconductor device according to claim 1,
wherein the oxide semiconductor layer further comprises a second region adjacent to the channel region, the second region comprising a second edge opposite to the first edge, and
the second region has a higher electrical conductivity than each of the source region and the drain region.

10. The semiconductor device according to claim 1, wherein the first region does not contain the impurity element.

11. The semiconductor device according to claim 1, wherein the etching solution contains nitric acid and acetic acid.

12. The semiconductor device according to claim 1, wherein an etching rate of the oxide semiconductor layer is less than 5 nm/min when the oxide semiconductor layer is etched using 0.5% of a hydrofluoric acid solution at room temperature.

13. The semiconductor device according to claim 1,
wherein the oxide semiconductor layer is formed by performing a heat treatment on an oxide semiconductor film having an amorphous structure, and
an etching rate of the oxide semiconductor film is greater than or equal to 100 nm/min when the oxide semiconductor film is etched using the etching solution at 40° C.

14. The semiconductor device according to claim 1,
wherein the oxide semiconductor layer comprises a plurality of metal elements,
the plurality of metal elements comprises indium, and
an atomic ratio of the indium to the plurality of metal elements is greater than or equal to 50%.

15. A semiconductor device comprising:
a gate electrode extending in a first direction;
an oxide semiconductor layer having a polycrystalline structure, the oxide semiconductor layer comprising a first edge and a second edge each extending in a second direction orthogonal to the first direction;
a gate insulating layer between the gate electrode and the oxide semiconductor layer;
a source electrode over the oxide semiconductor layer; and
a drain electrode over the oxide semiconductor layer,
wherein in a plan view, the oxide semiconductor layer comprises:
a first region overlapping the gate electrode,
a source region containing an impurity element adjacent to the first region, the source region electrically connected to the source electrode through a first contact hole,
a drain region containing the impurity element adjacent to the first region, the drain region electrically connected to the drain electrode through a second contact hole,
a second region surrounded by the source region, the second region comprising a first part of the first edge,
a third region surrounded by the source region, the third region comprising a first part of the second edge,
a fourth region surrounded by the drain region, the fourth region comprising a second part of the first edge, and
a fifth region surrounded by the drain region, the fifth region comprising a second part of the second edge,
each of the first region, the second region, the third region, the fourth region, and the fifth region has a higher electrical resistivity than each of the source region and the drain region, and
an etching rate of the oxide semiconductor layer is less than 3 nm/min when the oxide semiconductor layer is etched using an etching solution containing phosphoric acid as a main component at 40° C.

16. The semiconductor device according to claim 15, wherein in the plan view, each of the first region, the second region, the third region, the fourth region, and the fifth region overlaps a metal layer formed in a same layer as the gate electrode.

17. The semiconductor device according to claim 15, wherein each of the first region, the second region, the third region, the fourth region, and the fifth region does not contain the impurity element.

18. A semiconductor device comprising:
a gate electrode extending in a first direction;
an oxide semiconductor layer having a polycrystalline structure, the oxide semiconductor layer comprising a first edge and a second edge each extending in a second direction orthogonal to the first direction;
a gate insulating layer between the gate electrode and the oxide semiconductor layer;
a source electrode over the oxide semiconductor layer; and
a drain electrode over the oxide semiconductor layer,
wherein in a plan view, the oxide semiconductor layer comprises:
a first region overlapping the gate electrode,
a source region containing an impurity element adjacent to the first region, the source region electrically connected to the source electrode through a first contact hole, and
a drain region containing the impurity element adjacent to the first region, the drain region electrically connected to the drain electrode through a second contact hole,
the first region has a higher electrical resistivity than each of the source region and the drain region,
in the plan view, a first distance from the first edge to the first contact hole in the first direction is greater than a second distance from the first region to the first contact hole in the second direction, and
an etching rate of the oxide semiconductor layer is less than 3 nm/min when the oxide semiconductor layer is etched at 40° C. using an etching solution containing phosphoric acid as a main component.

19. The semiconductor device according to claim 18, wherein the first region does not contain the impurity element.
